(19) United States
(12) Patent Application Publication
(10) Pub. No.: US 2011/0308583 A1
(43) Pub. Date: Dec. 22, 2011

(54) PLASMA TREATMENT AT A P-I JUNCTION FOR INCREASING OPEN CIRCUIT VOLTAGE OF A PHOTOVOLTAIC DEVICE

(75) Inventors: Pratik P. Joshi, Cliffside Park, NJ (US); Young-Hee Kim, Mohegan Lake, NY (US)

(73) Assignee: International Business Machines Corporation, Armonk, NY (US)

(21) Appl. No.: 12/816,528

(22) Filed: Jun. 16, 2010

(51) Int. Cl. H01L 31/00; H01L 31/0232; H01L 31/18

(52) U.S. Cl. 136/255; 438/96; 438/72; 977/773; 257/E31.004; 257/E31.127; 257/E31.119

(57) ABSTRACT

Open circuit voltage of a photovoltaic device including a p-i-n junction including amorphous silicon-containing semiconductor materials is increased by a high power plasma treatment on an amorphous p-doped silicon-containing semiconductor layer before depositing an amorphous intrinsic silicon-containing semiconductor layer. The high power plasma treatment deposits a thin layer of nanocrystalline silicon-containing semiconductor material or converts a surface layer of the amorphous p-doped silicon containing layer into a thin nanocrystalline silicon-containing semiconductor layer. After deposition of an intrinsic amorphous silicon layer, the thin nanocrystalline silicon-containing semiconductor layer functions as an interfacial nanocrystalline silicon-containing semiconductor layer located at a p-i junction. The increase in the open circuit voltage of the photovoltaic device through the plasma treatment depends on the composition of the interfacial crystalline silicon-containing semiconductor layer, and particularly on the atomic concentration of carbon in the interfacial crystalline silicon-containing semiconductor layer.

### BACKGROUND

The present disclosure relates to a plasma treatment process for forming a photovoltaic device, and more particularly to a plasma treatment process applied at a p-i junction for increasing open circuit voltage of a photovoltaic device and a photovoltaic device thereby formed and including an interfacial nanocrystalline layer.

A photovoltaic device is a device that converts the energy of incident photons to electromotive force (e.m.f.). Typical photovoltaic devices include solar cells, which are configured to convert the energy in the electromagnetic radiation from the Sun to electric energy. Each photon has an energy given by the formula E=hν, in which the energy E is equal to the product of the Plank constant h and the frequency ν of the electromagnetic radiation associated with the photon.

A photon having energy greater than the electron binding energy of a matter can interact with the matter and free an electron from the matter. While the probability of interaction of each photon with each atom is probabilistic, a structure can be built with a sufficient thickness to cause interaction of photons with the structure with high probability. When an electron is knocked off an atom by a photon, the energy of the photon is converted to electrostatic energy and kinetic energy of the electron, the atom, and/or the crystal lattice including the atom. The electron does not need to have sufficient energy to escape the ionized atom. In the case of a material having a band structure, the electron can merely make a transition to a different band in order to absorb the energy from the photon.

The positive charge of the ionized atom can remain localized on the ionized atom, or can be shared in the lattice including the atom. When the positive charge is shared by the entire lattice, thereby becoming a non-localized charge, this charge is described as a hole in a valence band of the lattice including the atom. Likewise, the electron can be non-localized and shared by all atoms in the lattice. This situation occurs in a semiconductor material, and is referred to as photogeneration of an electron-hole pair. The formation of electron-hole pairs and the efficiency of photogeneration depend on the band structure of the irradiated material and the energy of the photon. In case the irradiated material is a semiconductor material, photogeneration occurs when the energy of a photon exceeds the band gap energy, i.e., the energy difference of a band gap of the irradiated material.

The direction of travel of charged particles, i.e., the electrons and holes, in an irradiated material is sufficiently random. Thus, in the absence of any electrical bias, photogeneration of electron-hole pairs merely results in heating of the irradiated material. However, an external field can break the spatial direction of the travel of the charged particles to harness the electrons and holes formed by photogeneration.

One exemplary method of providing an electric field is to form a p-i-n junction around the irradiated material. As negative charges accumulate in the p-doped region and positive charges accumulate in the n-doped region, an electric field is generated from the direction of the n-doped region toward the p-doped region. Electrons generated in the intrinsic region drifts toward the n-doped region due to the electric field, and holes generated in the intrinsic region drifts toward the p-doped region. Thus, the electron-hole pairs are collected systematically to provide positive charges at the p-doped region and negative charges at the n-doped region. The p-i-n junction forms the core of this type of photovoltaic device, which provides electromotive force that can power any device connected to the positive node at the p-doped region and the negative node at the n-doped region.

### BRIEF SUMMARY

Open circuit voltage of a photovoltaic device including a p-i-n junction including amorphous silicon-containing semiconductor materials is increased by a high power plasma treatment on an amorphous p-doped silicon-containing semiconductor layer before depositing an amorphous intrinsic silicon-containing semiconductor layer. The high power plasma treatment deposits a thin layer of nanocrystalline silicon-containing semiconductor material or converts a surface layer of the amorphous p-doped silicon containing layer into a thin nanocrystalline silicon-containing semiconductor layer. After deposition of an intrinsic amorphous silicon layer, the thin nanocrystalline silicon-containing semiconductor layer functions as an interfacial nanocrystalline silicon-containing semiconductor layer located at a p-i junction. The increase in the open circuit voltage of the photovoltaic device through the plasma treatment depends on the composition of the interfacial nanocrystalline silicon-containing semiconductor layer, and particularly on the atomic concentration of carbon in the interfacial nanocrystalline silicon-containing semiconductor layer. The increase in open circuit voltage of a photovoltaic device through the plasma treatment also depends on the plasma process parameters such as plasma power.

According to an aspect of the present disclosure, a method of forming a photovoltaic device is provided, which includes: forming an amorphous p-doped silicon-containing semiconductor layer on a substrate; and performing a plasma treatment on a surface of the p-doped silicon-containing semiconductor layer, wherein a nanocrystalline silicon-containing semiconductor layer is formed on the amorphous p-doped silicon-containing semiconductor layer by the plasma treatment.

According to another aspect of the present disclosure, a photovoltaic device is provided, which includes an amorphous p-doped silicon-containing semiconductor layer located on a substrate; and a nanocrystalline silicon-containing semiconductor layer contacting a surface of the amorphous p-doped silicon-containing semiconductor layer.

### BRIEF DESCRIPTION OF THE SEVERAL VIEWS OF THE DRAWINGS

FIG. 1 is an equivalent circuit for the prior art photovoltaic device structure of FIG. 1.

FIG. 2 is a schematic graph of an I-V curve of the prior art photovoltaic device structure of FIG. 1.

FIG. 3A is a vertical cross-sectional view of an exemplary photovoltaic device structure after formation of a transparent conductive material layer according to an embodiment of the present disclosure.

FIG. 3B is a vertical cross-sectional view of the exemplary photovoltaic device structure after formation of an amorphous p-doped silicon-containing semiconductor layer according to an embodiment of the present disclosure.

FIG. 3C is a vertical cross-sectional view of the exemplary photovoltaic device structure after formation of a nanocrystalline silicon-containing semiconductor layer according to an embodiment of the present disclosure.

FIG. 3D is a vertical cross-sectional view of there exemplary photovoltaic device structure after formation of back reflector layers according to embodiments of the present disclosure.

FIG. 4 is a graph that illustrates the impact of process parameters during the plasma treatment on open circuit voltage (V_{oc}). The letters A, B, C and D represent different processes employed for the plasma treatments that employ a variety of gases and plasma process parameters.

### DETAILED DESCRIPTION

As stated above, the present disclosure relates to a plasma treatment process applied at a p-i junction for increasing open circuit voltage of a photovoltaic device and a photovoltaic device thereby formed and including an interfacial nanocrystalline layer, which are now described in detail with accompanying figures. Throughout the drawings, the same reference numerals or letters are used to designate like or equivalent elements. The drawings are not necessarily drawn to scale.

As used herein, a crystal structure is “nanocrystalline” if the average grain size of the material is from 1 nm to 1 micron.

As used herein, a “silicon-containing semiconductor” or a “silicon-containing semiconductor material” is a semiconductor material that includes silicon.

As used herein, a “silicon-containing reactant gas” is a gas that includes at least one silicon atom in a molecule thereof and is capable of depositing silicon under suitable process conditions. Non-limiting examples of a silicon-containing reactant gas include SiH₄, SiH₂Cl₂, SiHCl₃, SiCl₄, and Si₂H₆.

As used herein, a “germanium-containing reactant gas” is a gas that includes at least one germanium atom in a molecule thereof and is capable of depositing germanium under suitable process conditions. Non-limiting examples of a germanium-containing reactant gas include GeH₄, GeH₂Cl₂, GeCl₄, and Ge₂H₆.

As used herein, a “carbon-containing reactant gas” is a gas that includes at least one carbon atom in a molecule thereof and is capable of depositing carbon under suitable process conditions. Non-limiting examples of a silicon-containing reactant gas include CH₄, C₂H₂, C₂H₄, C₂H₆, C₃H₆, C₃H₈, and other hydrocarbon gases.

As used herein, a “hydrogenated” semiconductor material is a semiconductor material including incorporated hydrogen therein, which neutralizes dangling bonds in the semiconductor material and allows charge carriers to flow more freely.

As used herein, an element is “optically transparent” if the element is transparent in the visible electromagnetic spectral range having a wavelength from 400 nm to 800 nm.

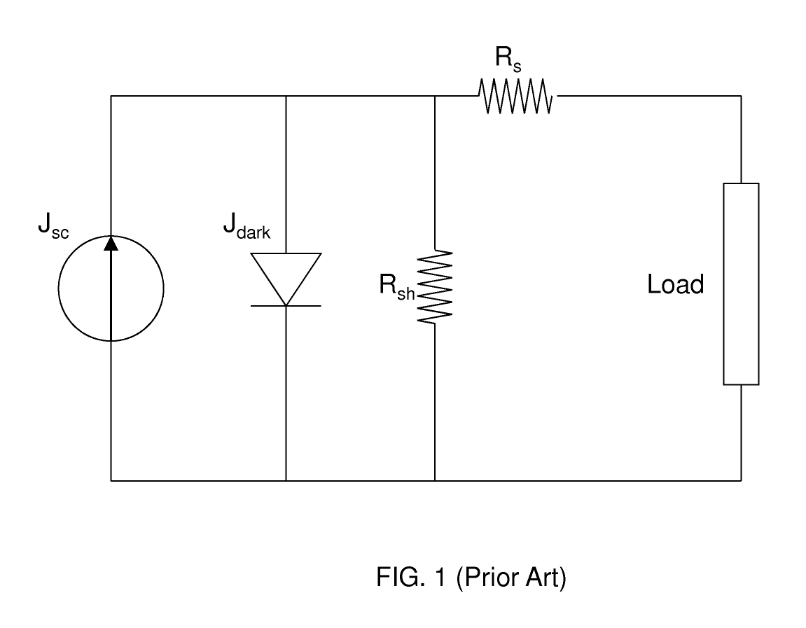

Referring to FIG. 1, the functionality of a photovoltaic device can be approximated by an equivalent circuit that includes a current source, a diode, and two resistors. The equivalent circuit of FIG. 1 approximates a unit area of the photovoltaic device, which provides electrical current that is proportional to the total irradiated area of the photovoltaic device. The photovoltaic current per unit area generated by the photovoltaic device is referred to as a short-circuit current density J_{sc}, i.e., the current density generated by the photovoltaic device if the positive node and the negative node of the photovoltaic device are electrically shorted. Thus, the current source in FIG. 1 generates an electrical current with a current density of the short-circuit current density J_{sc}.

Power dissipation through internal leakage current is approximated by a shunt resistance Rₛₕ. A finite value for the shunt resistance Rₛₕ triggers an internal leakage current through the photovoltaic device, and degrades the performance of the photovoltaic device. The lesser the shunt resistance Rₛₕ, the greater is the internal power loss due to the internal leakage current.

Power dissipation through internal resistance of the photovoltaic device is approximated by a series resistance Rₛ. A non-zero value for the series resistance Rₛ triggers Joule loss within the photovoltaic device. The greater the series resistance Rₛ the greater is the internal power loss due to the internal resistance of the photovoltaic device.

The potential difference between the positive node and the negative node of the photovoltaic device generates an internal current that flow in the opposite direction to the photocurrent, i.e., the current represented by the current source having the short-circuit current density J_{sc}. The dark current has the same functional dependence on the voltage across the current source as a diode current. Thus, the dark current is approximated by a diode that allows a reverse-direction current. The density of the dark current, i.e., the dark current per unit area of the photovoltaic device, is referred to as the dark current density J_{dark}. An external load can be attached to an outer node of the series resistor and one of the nodes of the current source. In FIG. 1, the value the impedance of the load is the value of the actual impedance of a physical load is divided by the area of the photovoltaic cell because the equivalent circuit of FIG. 1 describes the functionality of a unit area of the photovoltaic cell.

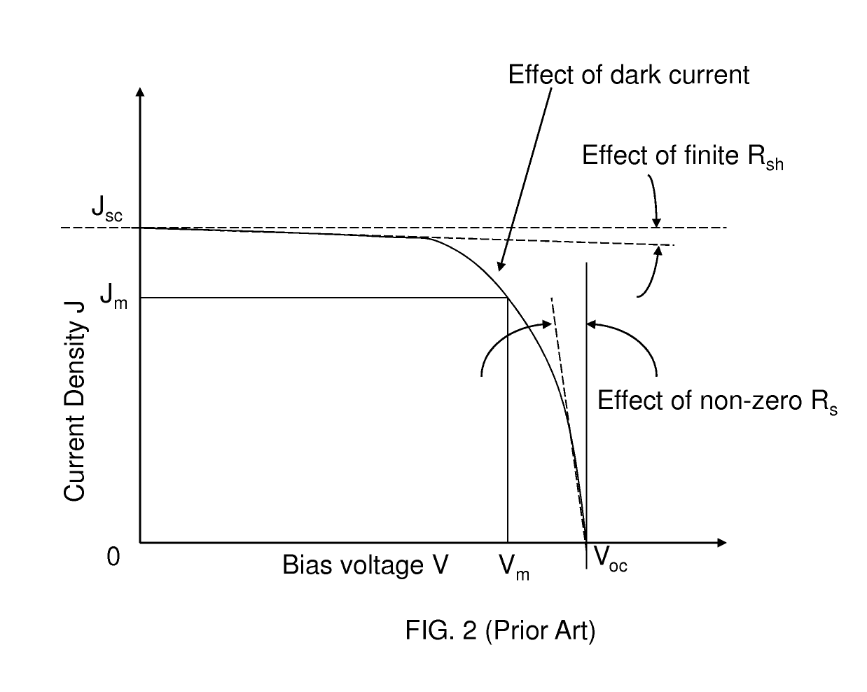

Referring to FIG. 2, a schematic graph of an I-V curve of a photovoltaic device structure is shown. The bias voltage V is the voltage across the load in the equivalent circuit of FIG. 1. The open circuit voltage Voc corresponds to the voltage across the load as the resistance of the load diverges to infinity, i.e., the voltage across the current source when the load is disconnected. The inverse of the absolute value of the slope of the I-V curve at V=0 and J=J_{sc} is approximately equal to the value of the shunt resistance Rₛₕ. The inverse of the absolute value of the slope of the I-V curve at V=V_{oc} and J=0 is approximately equal to the value of the series resistance Rₛ. The effect of the dark current is shown as an exponential decrease in the current density P, i.e., as a function of the bias voltage V around a non-zero value of the bias voltage.

The operating range of a photovoltaic device is the portion of the I-V curve in the first quadrant, i.e., when both the bias voltage V and the current density J are positive. The power density P, i.e., the density of power generated from an unit area of the photovoltaic device, is proportional to the product of the voltage V and the current density J along the I-V curve. The power density P reaches a maximum at a maximum power point of the I-V curve, which has the bias voltage of Vₘ and the current density of Jₘ. The fill factor FF is defined by the following formula:

$$FF = \frac{{J}_{m} \times {V}_{m}}{{J}_{sc} \times {V}_{oc}} . \qquad ( Eq . 1 )$$

The fill factor FF defines the degree by which the I-V curve of FIG. 2 approximates a rectangle. The fill factor FF is affected by the series resistance Rₛ and the shunt resistance Rₛₕ. The smaller the series resistance Rₛ, the greater the fill factor FF. The greater the shunt resistance Rₛₕ, the greater the fill factor FF. The theoretical maximum for the fill factor is 1.0.

The efficiency η of a photovoltaic device is the ratio of the power density at the maximum power point to the incident light power density Pₛ. In other words, the efficiency η is given by:

$$η = \frac{{J}_{m} \times {V}_{m}}{{P}_{s}} . \qquad ( Eq . 2 )$$

Eq. 2 can be rewritten as:

$$η = \frac{{J}_{sc} \times {V}_{oc} \times FF}{{P}_{s}} . \qquad ( Eq . 3 )$$

Thus, the efficiency h of a photovoltaic device is proportional to the short circuit current density J_{sc}, the open circuit voltage V_{oc}, and the fill factor FF.

The efficiency η of a photovoltaic device depends on the spectral composition of the incident light. For solar cells, the efficiency is calculated under a standard radiation condition defined as 1 sun, which employs the spectrum of the sunlight.

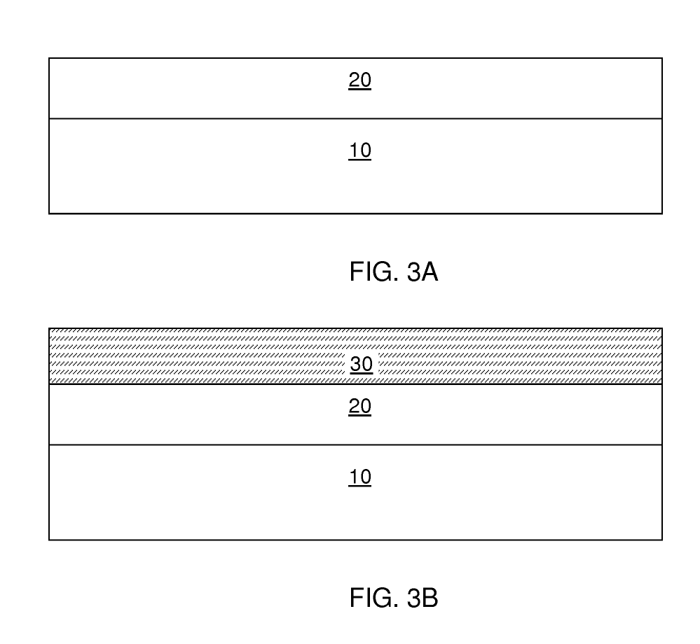

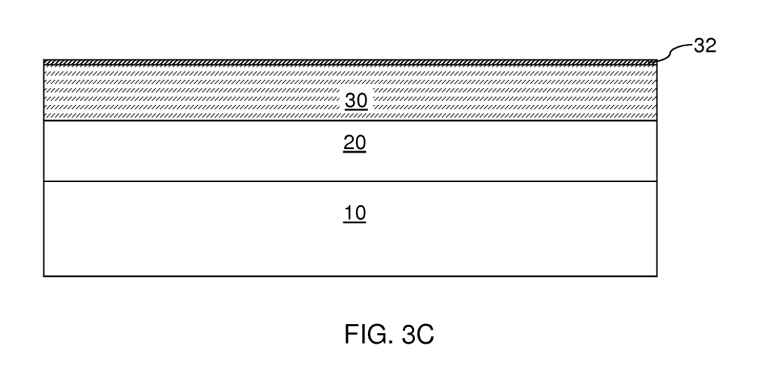

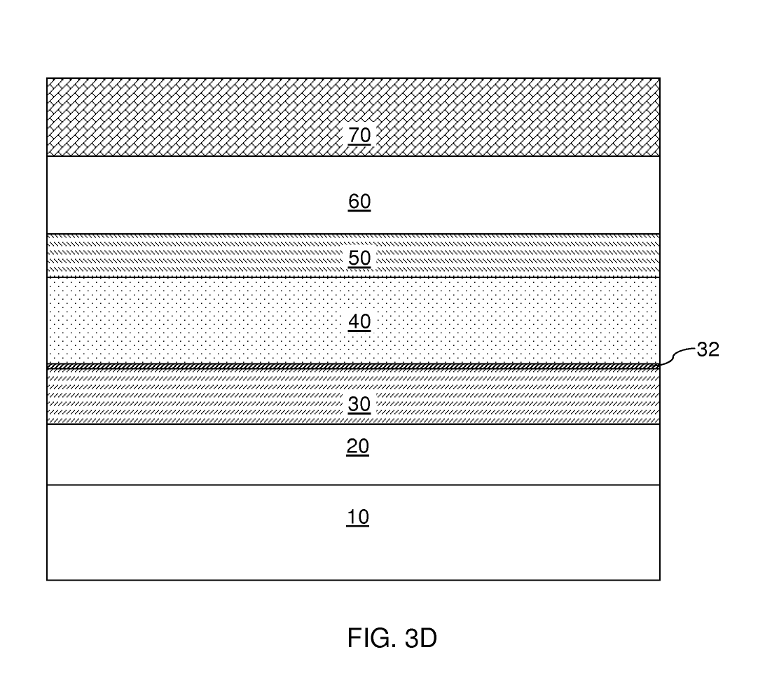

Referring to FIG. 3A, an exemplary photovoltaic device structure according to an embodiment of the present disclosure includes a stack of a substrate 10 and a transparent conductive material layer 20.

The substrate 10 is a structure that provides mechanical support to the photovoltaic structure. The substrate 10 is transparent in the range of electromagnetic radiation at which photogeneration of electrons and holes occur within the photovoltaic structure. If the photovoltaic device is a solar cell, the substrate 10 can be optically transparent. The substrate 10 can be a glass substrate. The thickness of the substrate 10 can be from 50 microns to 3 mm, although lesser and greater thicknesses can also be employed.

The transparent conductive material layer 20 includes a material that is transparent in the range of electromagnetic radiation at which photogeneration of electrons and holes occur within the photovoltaic device structure. If the photovoltaic device structure is employed as a solar cell, the transparent conductive material layer 20 can be optically transparent. For example, the transparent conductive material layer 20 can include a transparent conductive oxide such as a fluorine-doped tin oxide (SnO₂:F), an aluminum-doped zinc oxide (ZnO:Al), or indium tin oxide. The transparent conductive material layer 20 can be deposited, for example, by chemical vapor deposition (CVD). The thickness of the transparent conductive material layer 20 can be from 300 nm to 3 microns, although lesser and greater thicknesses can also be employed.

Referring to FIG. 3B, an amorphous p-doped silicon-containing semiconductor layer 30 is formed on the top surface of the transparent conductive material layer 20. The amorphous p-doped silicon-containing semiconductor layer 30 includes an amorphous p-doped silicon-containing material. In some cases, the amorphous p-doped silicon-containing semiconductor layer 30 can include an amorphous hydrogenated p-doped silicon-containing material. The presence of hydrogen in the amorphous p-doped silicon-containing semiconductor layer 30 can increase the concentration of free charge carriers, i.e., holes, by delocalizing the electrical charges that are pinned to defect sites.

The amorphous p-doped silicon-containing semiconductor layer 30 can be deposited in a process chamber containing a silicon-containing reactant gas. Specifically, the amorphous p-doped silicon-containing semiconductor layer 30 can be formed on the transparent conductive material layer 20 in the presence of the silicon-containing reactant gas in a chemical vapor deposition. Non-limiting examples of a silicon-containing reactant gas include SiH₄, SiH₂Cl₂, SiHCl₃, SiCl₄, and Si₂H₆. The chemical vapor deposition process can be plasma enhanced chemical vapor process (PECVD) performed at a deposition temperature from 50° C. to 400° C., and preferably from 100° C. to 350° C., and at a pressure from 0.1 Torr to 10 Torr, and preferably from 0.2 Torr to 5 Torr.

Typically, a carrier gas is employed to deposit the amorphous p-doped silicon-containing semiconductor layer 30 in the process chamber. In case the carrier gas includes hydrogen, the amorphous p-doped silicon-containing semiconductor layer 30 includes a hydrogenated p-doped silicon-containing material. In this case, the silicon-containing reactant gas and the hydrogen carrier gas are concurrently supplied to the process chamber. Use of the hydrogen carrier gas facilitates the incorporation of hydrogen in the amorphous hydrogenated p-doped silicon-containing semiconductor layer 30. Specifically, the hydrogen atoms in the hydrogen carrier gas are incorporated into the deposited material to form an amorphous hydrogenated p-doped silicon-containing material of the amorphous p-doped silicon-containing semiconductor layer 30.

In case a PECVD process is employed, the plasma accelerates the rate of deposition. The power of the plasma is maintained at a relatively low level to ensure that the deposited material is amorphous because experimental data indicate a photovoltaic device including p-doped semiconductor layer consisting of a crystalline p-doped silicon-containing semiconductor material provides lesser open circuit voltage than a photovoltaic device including p-doped semiconductor layer consisting of an amorphous p-doped silicon-containing semiconductor material provided that dimensions and other components of both photovoltaic devices are the same. This trend holds true even when hydrogenated materials are employed for the p-doped semiconductor layer. Typically, plasma power less than 30 Watts is employed for a process chamber that processes a 200 mm diameter substrate.

The thickness of the amorphous p-doped silicon-containing semiconductor layer 30 can be from 5 nm to 300 nm, and preferably from 10 nm to 200 nm, although lesser and greater thicknesses can also be employed.

The amorphous p-doped silicon-containing semiconductor layer 30 includes silicon and p-type dopant atoms such as B, Ga, and In. In one embodiment, the amorphous p-doped silicon-containing semiconductor layer 30 consists of amorphous p-doped.

The p-type dopants in the p-doped silicon-containing material of the amorphous p-doped silicon-containing semiconductor layer 30 can be introduced by in-situ doping. The p-type dopants, which are electrical dopants that renders the doped material a p-type semiconductor material. The in-situ doping of the p-type dopants can be effected by adding a dopant gas including at least one p-type dopant, e.g., B, In, and Ga, into the gas stream into the process chamber. For example, B is the p-type dopant, the dopant gas can be B₂H₆ (diborane).

In one embodiment, the amorphous p-doped silicon-containing semiconductor layer 30 can include carbon. In this case, the amorphous p-doped silicon-containing semiconductor layer 30 includes an amorphous p-doped silicon-containing semiconductor alloy material, which includes at least silicon, carbon, and at least one p-type dopant.

The carbon atoms in the amorphous p-doped silicon-containing material of the amorphous p-doped silicon-containing semiconductor layer 30 can be introduced by in-situ doping as well. Carbon atoms are non-electrical dopants that do not render the doped material electrically active, i.e., does not provide any extra holes or extra electrons. The in-situ doping of the carbon atoms can be effected by adding a carbon-containing reactant gas into the gas stream into the process chamber. Non-limiting examples of a silicon-containing reactant gas include CH₄, C₂H₂, C₂H₄, C₂H₆, C₃H₆, C₃H₈, and other hydrocarbon gases.

In this case, the carbon-containing reactant gas can be flown into the processing chamber during deposition of the amorphous p-doped silicon-containing semiconductor layer 30. The atomic concentration of carbon in the amorphous silicon-containing semiconductor layer 30 can be from 1% to 90%, and preferably from 10% to 70%. In this case, the band gap of the amorphous p-doped silicon-containing semiconductor layer 30 can be from 1.7 eV to 2.1 eV. The carbon content in the amorphous silicon-containing semiconductor layer 30 can be graded within the amorphous silicon-containing semiconductor layer 30. For example, the atomic carbon concentration of the amorphous silicon-containing semiconductor layer 30 may decrease with distance from the interface with the transparent conductive material layer 20.

In one embodiment, the amorphous p-doped silicon-containing semiconductor layer 30 includes an amorphous p-doped silicon-containing semiconductor alloy that includes at least one semiconductor material other than silicon. The at least one semiconductor material other than silicon can be selected from, but is not limited to, germanium, a III-V compound semiconductor material, a II-VI compound semiconductor material, any other compound semiconductor material, or a combination thereof. In case the amorphous p-doped silicon-containing semiconductor layer 30 includes any additional semiconductor material other than silicon, at least another semiconductor-containing reactant gas can be supplied into the process chamber concurrently with the silicon-containing gas, the carrier gas, the dopant gas, and/or the carbon-containing reactant gas. The semiconductor-containing reactant gas can be a germanium-containing reactant gas that includes germanium, or can include at least one elements of a compound semiconductor material. Non-limiting examples of a germanium-containing reactant gas include GeH₄, GeH₂Cl₂, GeCl₄, and Ge₂H₆. The semiconductor-containing reactant gas can be concurrently flowed into the process chamber.

In an exemplary PECVD process, a stack of a substrate 10 and a transparent oxide material layer 20 having a diameter of 200 mm can be placed in a process chamber. The stack is placed such that the transparent oxide material layer 20 faces up toward a gas stream, and the temperature of the process chamber is set at 250° C. The pressure of the process chamber is set at 3 Tarr by maintaining a gas stream and a pumping system. The gas stream includes a combination of hydrogen gas at a flow rate of 250 sccm, silane gas at a flow rate of 50 sccm, a 1% diborane gas (with He balance gas) at a flow rate of 50 sccm, and propylene (C₃H₆) gas at a flow rate that changes from 3 sccm to 1 sccm over time. Plasma power of about 15 Watts is employed to cause the PECVD process to proceed, i.e., to cause deposition of the amorphous p-doped silicon-containing semiconductor layer 30 on the transparent oxide material layer 20. As discussed above, the power of the plasma is maintained at a relatively low setting (about 15 Watts) to ensure that the microscopic structure of the deposited material is amorphous. The power of the plasma in this case may be from 2 Watts to 100 Watts, and preferably from 10 Watts to 20 Watts.

Referring to FIG. 3C, a plasma treatment is performed on a surface of the p-doped silicon-containing semiconductor layer 30. Specifically, the surface of the amorphous p-doped silicon-containing semiconductor layer 30 is exposed to a flash of high power plasma. The plasma treatment forms a nanocrystalline silicon-containing semiconductor layer 32 formed on a surface of the amorphous p-doped silicon-containing semiconductor layer 30. The nanocrystalline silicon-containing semiconductor layer 32 is formed on the surface of the amorphous p-doped silicon-containing semiconductor layer 30 either by deposition of an additional semiconductor material or by conversion of a surface portion of the amorphous p-doped silicon-containing semiconductor layer 30. The power of the plasma is set such that the semiconductor material deposited thereby or the material converted thereby becomes nanocrystalline. The duration of the plasma treatment is limited so that the thickness of the nanocrystalline silicon-containing semiconductor layer 32 is from 0.5 nm to 5 nm. Typically, the duration of the plasma treatment can be from 0.1 second to 10 seconds, and preferably from 1 second to 5 seconds, although lesser and greater times can also be employed. Typically, the ratio of the thickness of the nanocrystalline silicon-containing semiconductor layer 32 to the thickness of the amorphous p-doped silicon-containing semiconductor layer 30 is from 0.005 to 0.1, and preferably from 0.005 to 0.02.

In one embodiment, the plasma treatment deposits the nanocrystalline silicon-containing semiconductor layer 32 on the amorphous p-doped silicon-containing semiconductor layer 30. The plasma treatment is performed employing an ambient that includes a silicon-containing reactant gas. The plasma treatment can deposit the nanocrystalline silicon-containing semiconductor layer 32 can include an electrically undoped semiconductor material, i.e., a semiconductor material does not include an electrical dopant, although embodiments in which a p-doped nanocrystalline silicon-containing semiconductor material is deposited during the plasma treatment can also be employed. In one exemplary case, the nanocrystalline silicon-containing semiconductor layer 32 can consist of nanocrystalline intrinsic silicon.

The ambient gas during the plasma treatment typically includes a carrier gas. For example, the plasma treatment can be performed in a hydrogen-containing ambient. The hydrogen-containing ambient includes hydrogen gas and a silicon-containing reactant gas. In this case, the material of the nanocrystalline silicon-containing semiconductor layer 32 is hydrogenated, i.e., a nanocrystalline hydrogenated silicon-containing semiconductor material is deposited in the nanocrystalline silicon-containing semiconductor layer 32.

Further, the ambient gas can further include a carbon-containing reactant gas. For example, the hydrogen-containing ambient can further include a carbon-containing reactant gas. The addition of the carbon-containing reactant gas to the ambient gas during the plasma treatment causes in-situ carbon doping of the nanocrystalline silicon-containing semiconductor layer 32. Thus, the nanocrystalline silicon-containing semiconductor layer 32 includes nanocrystalline silicon-carbon alloy. While the nanocrystalline silicon-carbon alloy is typically intrinsic, embodiments in which the nanocrystalline silicon-carbon alloy is p-doped can also be employed. In case the nanocrystalline silicon-carbon alloy is intrinsic, the nanocrystalline silicon-containing semiconductor layer 32 is a nanocrystalline intrinsic carbon-doped silicon layer. In case the nanocrystalline silicon-carbon alloy is p-doped, for example, by adding a p-type dopant gas to the process chamber during the plasma treatment, the nanocrystalline silicon-containing semiconductor layer 32 is a nanocrystalline p-doped carbon-doped silicon layer.

During the research leading to the present disclosure, it has been discovered that the open circuit voltage of the exemplary photovoltaic device structure depends on the concentration of the carbon in the nanocrystalline silicon-containing semiconductor layer 32 in a non-linear way. Specifically, an optimum concentration of carbon within the nanocrystalline silicon-containing semiconductor layer 32 exists such that the open circuit voltage of the exemplary photovoltaic device structure achieves a maximum at the optimum concentration of carbon. In order to increase the open circuit voltage of the exemplary photovoltaic device structure, the nanocrystalline silicon-containing semiconductor layer 32 can be deposited in a process chamber to which a silicon-containing reactant gas and a carbon-containing reactant gas are supplied such that a ratio of total carbon atoms in the carbon-containing reactant gas to total silicon atoms in the silicon-containing reactant gas is greater than 0 and is less than 0.75, and preferably from 0.05 to 0.50, and more preferably from 0.10 to 0.25.

The plasma treatment can be performed in the same process chamber as the process chamber employed for the deposition of the amorphous p-doped silicon-containing semiconductor layer 30 by PECVD. For example, the amorphous p-doped silicon-containing semiconductor layer 30 can be deposited in a plasma enhanced chemical vapor deposition process employing a plasma applied at a first plasma power, and the plasma treatment can employ a plasma applied at a second plasma power. The first plasma power is set such that the deposited material does not acquire enough kinetic energy to cause atoms on the surface of the deposited material to diffuse sufficiently and to form a nanocrystalline structure. The second plasma power is set such that the deposited material acquires enough kinetic energy for surface diffusion and to form a nanocrystalline structure in the nanocrystalline silicon-containing semiconductor layer 32. Thus, the second plasma power is greater than the first plasma power. Typically, the second power is greater than the first plasma power by a factor from 10 to 1,000, although lesser and greater ratios can also be employed.

In some cases, the nanocrystalline silicon-containing semiconductor layer 32 includes a nanocrystalline silicon-containing semiconductor alloy that includes at least one semiconductor material other than silicon. The at least one semiconductor material other than silicon can be selected from, but is not limited to, germanium, a III-V compound semiconductor material, a II-VI compound semiconductor material, any other compound semiconductor material, or a combination thereof. At least another semiconductor-containing reactant gas can be supplied into the process chamber concurrently with the silicon-containing gas, the carrier gas, and/or the carbon-containing reactant gas during the plasma treatment. The semiconductor-containing reactant gas can be a germanium-containing reactant gas that includes germanium, or can include at least one elements of a compound semiconductor material. Non-limiting examples of a germanium-containing reactant gas include GeH₄, GeH₂Cl₂, GeCl₄, and Ge₂H₆. The semiconductor-containing reactant gas can be concurrently flowed into the process chamber.

In an exemplary plasma treatment process that deposits the nanocrystalline silicon-containing semiconductor layer 32, a stack of the substrate 10, the transparent oxide material layer 20, and the p-doped silicon-containing semiconductor layer 30 having a diameter of 200 mm can be placed in a process chamber. The stack is placed such that a top surface of the p-doped silicon-containing semiconductor layer 30 can subsequently be exposed to a plasma, and the temperature of the process chamber is set at 250° C. The pressure of the process chamber is set at 8 Torr by maintaining a gas stream and a pumping system. In general, the pressure of the process chamber can be from 2 Torr to 20 Torr. The gas stream includes a combination of hydrogen gas at a flow rate from 500 sccm to 4,000 sccm, a silicon-containing reactant gas (e.g., silane) at a flow rate from 10 scan to 100 sccm, and optionally a carbon-containing reactant gas (e.g., propylene) at a flow rate from 0 sccm to 20 sccm. Plasma power of about 2,000 Watts (2 kW) is employed during the plasma treatment. The power of the plasma during the treatment may be from 500 Watts to 10,000 Watts, and preferably from 1,000 Watts to 5,000 Watts.

In another embodiment, the plasma treatment converts a surface portion of the amorphous p-doped silicon-containing semiconductor layer 30 into the nanocrystalline silicon-containing semiconductor layer 32. The plasma treatment is performed without flowing a silicon-containing reactant gas during the plasma treatment. The plasma treatment does not deposit a new semiconductor material, but converts an existing surface portion of the amorphous p-doped silicon-containing semiconductor layer 30 into the nanocrystalline silicon-containing semiconductor layer 32 by changing the microscopic crystalline structure from an amorphous phase to a nanocrystalline phase. Because the amorphous p-doped silicon-containing semiconductor layer 30 includes p-type dopants, the nanocrystalline silicon-containing semiconductor layer 32 also includes p-type dopants. The ambient gas during the plasma treatment typically includes hydrogen gas. This, the plasma treatment can be performed in a hydrogen-containing ambient.

The plasma treatment can be performed in the same process chamber as the process chamber employed for the deposition of the amorphous p-doped silicon-containing semiconductor layer 30 by PECVD. For example, the amorphous p-doped silicon-containing semiconductor layer 30 can be deposited in a plasma enhanced chemical vapor deposition process employing a plasma applied at a first plasma power, and the plasma treatment can employ a plasma applied at a second plasma power. The first plasma power is set such that the deposited material does not acquire enough kinetic energy to cause atoms on the surface of the deposited material to diffuse sufficiently and to form a nanocrystalline structure. The second plasma power is set such that the semiconductor material on the surface portion of the amorphous p-doped silicon-containing semiconductor layer 30 acquires enough kinetic energy from the plasma so that atoms crystallize at the surface to form a nanocrystalline structure, thereby forming the nanocrystalline silicon-containing semiconductor layer 32. Thus, the second plasma power is greater than the first plasma power. Typically, the second power is greater than the first plasma power by a factor from 10 to 1,000, although lesser and greater ratios can also be employed.

The composition of the nanocrystalline silicon-containing semiconductor layer 32 depends on the composition of the amorphous p-doped silicon-containing semiconductor layer 30. If the p-doped silicon-containing semiconductor layer 30 is an amorphous p-doped silicon layer, the nanocrystalline silicon-containing semiconductor layer 32 is a nanocrystalline p-doped silicon layer. If the p-doped silicon-containing semiconductor layer 30 is an amorphous p-doped silicon-containing semiconductor alloy layer, the nanocrystalline silicon-containing semiconductor layer 32 is a nanocrystalline p-doped silicon-containing semiconductor alloy layer. If the p-doped silicon-containing semiconductor layer 30 is an amorphous p-doped carbon-doped silicon-containing layer, the nanocrystalline silicon-containing semiconductor layer 32 is a nanocrystalline p-doped carbon-doped silicon-containing layer.

In an exemplary plasma treatment process that converts a surface portion of the amorphous p-doped silicon-containing semiconductor layer 30 into the nanocrystalline silicon-containing semiconductor layer 32, a stack of the substrate 10, the transparent oxide material layer 20, and the p-doped silicon-containing semiconductor layer 30 having a diameter of 200 mm can be placed in a process chamber. The stack is placed such that a top surface of the p-doped silicon-containing semiconductor layer 30 can subsequently be exposed to a plasma, and the temperature of the process chamber is set at 250° C. The pressure of the process chamber is set at 8 Torr by maintaining a gas stream and a pumping system. In general, the pressure of the process chamber can be from 2 Torr to 20 Torr. The gas stream includes hydrogen gas at a flow rate from 500 sccm to 4,000 sccm. Plasma power of about 2,000 Watts (2 kW) is employed during the plasma treatment. The power of the plasma during the treatment may be from 500 Watts to 10,000 Watts, and preferably from 1,000 Watts to 5,000 Watts.

Referring to FIG. 3D, an intrinsic semiconductor layer 40 is deposited on the amorphous p-doped silicon-containing semiconductor layer 30, for example, by plasma-enhanced chemical vapor deposition. The intrinsic hydrogenated silicon-containing material can be amorphous or microcrystalline. Typically, the intrinsic hydrogenated silicon-containing material is amorphous.

Preferably, the intrinsic semiconductor layer 40 includes an intrinsic hydrogenated silicon-containing material. The intrinsic hydrogenated silicon-containing material can be deposited in a process chamber containing a silicon-containing reactant gas a carrier gas including hydrogen. Hydrogen atoms in the hydrogen gas within the carrier gas are incorporated into the deposited material to form the intrinsic hydrogenated silicon-containing material of the intrinsic semiconductor layer 40. The thickness of the intrinsic semiconductor layer 40 depends on the diffusion length of electrons and holes in the intrinsic hydrogenated silicon-containing material. Typically, the thickness of the intrinsic semiconductor layer 40 is from 100 nm to 1 micron, although lesser and greater thicknesses can also be employed.

In an exemplary PECVD process for deposition of the intrinsic semiconductor layer 40, a stack of the substrate 10, the transparent oxide material layer 20, the p-doped silicon-containing semiconductor layer 30, and the nanocrystalline silicon-containing semiconductor layer 32 having a diameter of 200 mm can be placed in a process chamber. The stack is placed such that the nanocrystalline silicon-containing semiconductor layer 32 can subsequently be exposed to a plasma, and the temperature of the process chamber is set at 250° C. The pressure of the process chamber is set at 4 Torr by maintaining a gas stream and a pumping system. The gas stream includes a combination of hydrogen gas at a flow rate of 1,000 sccm and silane gas at a flow rate of 50 sccm. Plasma power of about 25 Watts is employed to cause the PECVD process to proceed, i.e., to cause deposition of the intrinsic semiconductor layer 40, in which case an amorphous intrinsic silicon layer is deposited as the intrinsic semiconductor layer 40. The power of the plasma in this case may be from 2 Watts to 100 Watts, and preferably from 10 Watts to 20 Watts.

Subsequently, an n-doped semiconductor layer 50 is deposited on the intrinsic semiconductor layer 40, for example, by plasma-enhanced chemical vapor deposition. The n-doped semiconductor layer 50 includes an n-doped silicon-containing material. In case the n-doped semiconductor layer 50 includes an n-doped hydrogenated silicon-containing material, hydrogen gas is supplied into the process chamber concurrently with a silicon-containing reactant gas. The material of the n-doped semiconductor layer 50 can be amorphous or microcrystalline.

The n-type dopants in the n-doped semiconductor layer 50 can be introduced by in-situ doping. For example, phosphene (PH₃) gas or arsine (AsH₃) gas can be flown into the processing chamber concurrently with the silicon-containing reactant gas if the n-doped semiconductor layer 50 includes an n-doped silicon-containing material or an n-doped germanium-containing material. If the n-doped semiconductor layer 50 includes an n-doped compound semiconductor material, the ratio of the flow rate of the reactant gas for the Group II or Group III material to the flow rate of the reactant gas for the group VI or Group V material can be decreased to induce n-type doping. Alternately, the n-type dopants in the n-doped semiconductor layer 50 can be introduced by subsequent introduction of dopants employing any method known in the art. The thickness of the n-doped semiconductor layer 50 can be from 6 nm to 60 nm, although lesser and greater thicknesses can also be employed.

The first back reflector layer 60 is deposited on the n-doped semiconductor layer 50 employing methods known in the art. The first back reflector layer 60 includes a transparent conductive material. The second back reflector layer 70 is subsequently deposited on the first back reflector layer 70, for example, by electroplating, electroless plating, physical vapor deposition, chemical vapor deposition, vacuum evaporation, or a combination thereof. The second back reflector layer 70 can be a metallic layer.

The first back reflector layer 60 includes a transparent conductive material that is transparent in the range of electromagnetic radiation at which photogeneration of electrons and holes occur within the photovoltaic device structure. If the photovoltaic device structure is employed as a solar cell, the first back reflector layer 60 can be optically transparent. For example, the first back reflector layer 60 can include a transparent conductive oxide such as a fluorine-doped tin oxide (SnO₂:F), an aluminum-doped zinc oxide (ZnO:Al), or indium tin oxide. Since such transparent conductive oxide materials are n-type materials, the contact between the first back reflector layer 60 and the n-doped semiconductor layer 50 is Ohmic, and as such, the contact resistance between the first back reflector layer 60 and the n-doped semiconductor layer 50 is negligible. The thickness of the back reflector layer 60 can be from 25 nm to 250 nm, although lesser and greater thicknesses can also be employed.

The second back reflector layer 70 includes a metallic material. Preferably, the metallic material has a high reflectivity in the range of electromagnetic radiation at which photogeneration of electrons and holes occur within the photovoltaic device structure. The metallic material can include silver, aluminum, or an alloy thereof. The thickness of the second back reflector layer 70 can be from 100 nm to 1 micron, although lesser and greater thicknesses can also be employed.

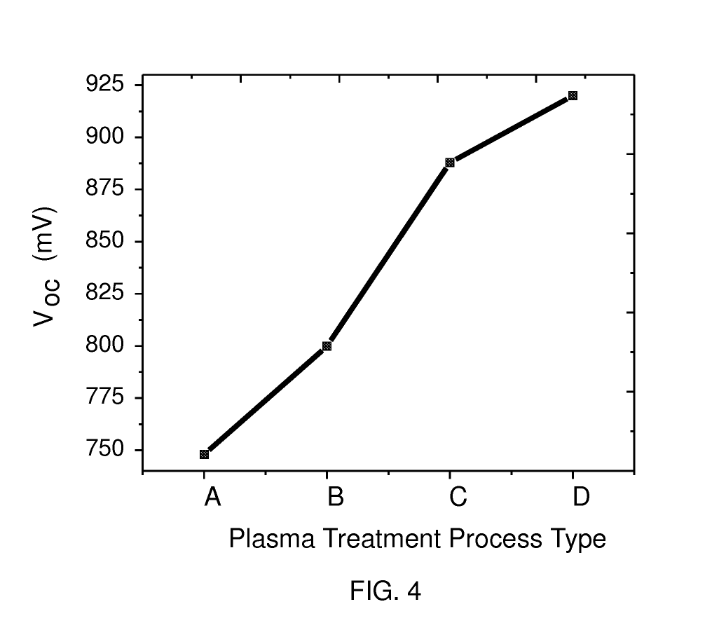

Referring to FIG. 4, a graph illustrates the impact of process parameters during the plasma treatment on open circuit voltage (V_{oc}) of various samples of the exemplary photovoltaic device structure of FIG. 3D. The letters A, B, C and D represent different processes employed for the plasma treatments that employ a variety of gases and plasma process parameters. In the illustrated examples, the amorphous p-doped silicon-containing semiconductor layer 20 is an amorphous hydrogenated p-doped silicon layer, the intrinsic semiconductor layer 40 is an amorphous hydrogenated intrinsic silicon layer, and the n-doped semiconductor layer 50 is an amorphous hydrogenated n-doped silicon layer.

In a first plasma treatment process, designated as plasma treatment process type A, a stack of the substrate 10, the transparent oxide material layer 20, and the p-doped silicon-containing semiconductor layer 30 having a diameter of 200 mm is placed in a process chamber. The temperature of the process chamber is set at 250° C. The pressure of the process chamber is set at 8 Torr by maintaining a gas stream and a pumping system. The gas stream includes a combination of hydrogen gas at a flow rate of 2,000 sccm, silane gas at a flow rate of 40 sccm, and propylene gas at a flow rate of 10 sccm. Plasma power of 2,000 Watts (2 kW) is employed during the plasma treatment, which lasts 3.5 seconds. When this plasma treatment process was employed to form the nanocrystalline silicon-containing semiconductor layer 32 in a first sample of the exemplary photovoltaic device structure, the first sample of the exemplary photovoltaic device structure generated an open circuit voltage of about 750 mV as shown in FIG. 4.

In a second plasma treatment process, designated as plasma treatment process type B, a stack of the substrate 10, the transparent oxide material layer 20, and the p-doped silicon-containing semiconductor layer 30 having a diameter of 200 mm is placed in a process chamber. The temperature of the process chamber is set at 250° C. The pressure of the process chamber is set at 8 Torr by maintaining a gas stream and a pumping system. The gas stream consists of hydrogen gas at a flow rate of 2,000 sccm. Plasma power of 2,000 Watts (2 kW) is employed during the plasma treatment, which lasts 3.5 seconds. When this plasma treatment process was employed to form the nanocrystalline silicon-containing semiconductor layer 32 in a second sample of the exemplary photovoltaic device structure, the second sample of the exemplary photovoltaic device structure generated an open circuit voltage of about 800 mV as shown in FIG. 4.

In a third plasma treatment process, designated as plasma treatment process type C, a stack of the substrate 10, the transparent oxide material layer 20, and the p-doped silicon-containing semiconductor layer 30 having a diameter of 200 mm is placed in a process chamber. The temperature of the process chamber is set at 250° C. The pressure of the process chamber is set at 8 Torr by maintaining a gas stream and a pumping system. The gas stream includes a combination of hydrogen gas at a flow rate of 2,000 sccm and silane gas at a flow rate of 40 sccm, and does not include any carbon-containing reactant gas. Plasma power of 2,000 Watts (2 kW) is employed during the plasma treatment, which lasts 3.5 seconds. When this plasma treatment process was employed to form the nanocrystalline silicon-containing semiconductor layer 32 in a third sample of the exemplary photovoltaic device structure, the third sample of the exemplary photovoltaic device structure generated an open circuit voltage of about 888 mV as shown in FIG. 4.

In a fourth plasma treatment process, designated as plasma treatment process type D, a stack of the substrate 10, the transparent oxide material layer 20, and the p-doped silicon-containing semiconductor layer 30 having a diameter of 200 mm is placed in a process chamber. The temperature of the process chamber is set at 250° C. The pressure of the process chamber is set at 8 Ton by maintaining a gas stream and a pumping system. The gas stream includes a combination of hydrogen gas at a flow rate of 2,000 sccm, silane gas at a flow rate of 40 sccm, and propylene gas at a flow rate of 2 sccm. Plasma power of 2,000 Watts (2 kW) is employed during the plasma treatment, which lasts 3.5 seconds. When this plasma treatment process was employed to form the nanocrystalline silicon-containing semiconductor layer 32 in a fourth sample of the exemplary photovoltaic device structure, the fourth sample of the exemplary photovoltaic device structure generated an open circuit voltage of about 920 mV as shown in FIG. 4.

As illustrated by the data for the plasma treatment process types B, C, and D, the exemplary photovoltaic device can have an open circuit voltage that is equal to or greater than 800 mV. Further, comparison of the data for the plasma treatment process types A, C, and D clearly shows that an optimal ratio of total carbon atoms in the carbon-containing reactant gas to total silicon atoms in the silicon-containing reactant gas exists. Further, the data in FIG. 4 shows that the optimal ratio can be a number greater than 0 and is less than 0.75 in case the silicon-containing reactant gas is silane and the carbon-containing reactant gas is propylene. Specifically, this ratio is 0.75 for A, 0 for C, and 0.15 D. Among the four plasma treatment process types A, B, C, and D, the plasma treatment process type D provides the greatest open circuit voltage.

While the present disclosure has been particularly shown and described with respect to preferred embodiments thereof, it will be understood by those skilled in the art that the foregoing and other changes in forms and details can be made without departing from the spirit and scope of the present disclosure. It is therefore intended that the present disclosure not be limited to the exact forms and details described and illustrated, but fall within the scope of the appended claims.

What is claimed is:

1. A method of forming a photovoltaic device comprising:
forming an amorphous p-doped silicon-containing semiconductor layer on a substrate; and
performing a plasma treatment on a surface of said p-doped silicon-containing semiconductor layer, wherein a nanocrystalline silicon-containing semiconductor layer is formed on said amorphous p-doped silicon-containing semiconductor layer by said plasma treatment.

2. The method of claim 1, wherein said nanocrystalline silicon-containing semiconductor layer includes carbon.

3. The method of claim 2, wherein said nanocrystalline silicon-containing semiconductor layer is a nanocrystalline intrinsic carbon-doped silicon layer or a nanocrystalline p-doped carbon-doped silicon layer.

4. The method of claim 3, wherein said amorphous p-doped silicon-containing semiconductor layer is an amorphous p-doped silicon layer, and said photovoltaic device has an open circuit voltage that is equal to or greater than 800 mV.

5. The method of claim 1, wherein said plasma treatment is performed in a hydrogen-containing ambient.

6. The method of claim 5, wherein said hydrogen-containing ambient includes hydrogen gas and a silicon-containing reactant gas.

7. The method of claim 6, wherein said hydrogen-containing ambient further includes a carbon-containing reactant gas.

8. The method of claim 7, wherein said nanocrystalline silicon-containing semiconductor layer is deposited in a process chamber to which a silicon-containing reactant gas and a carbon-containing reactant gas are supplied, wherein a ratio of total carbon atoms in said carbon-containing reactant gas to total silicon atoms in said silicon-containing reactant gas is greater than 0 and is less than 0.75.

9. The method of claim 1, wherein said amorphous p-doped silicon-containing semiconductor layer is deposited in a plasma enhanced chemical vapor deposition process employing a plasma applied at a first plasma power, and said plasma treatment employs a plasma applied at a second plasma power that is greater than said first plasma power.

10. The method of claim 9, wherein said second power is greater than said first plasma power by a factor from 10 to 1,000.

11. The method of claim 1, wherein said plasma treatment deposits said nanocrystalline silicon-containing semiconductor layer on said amorphous p-doped silicon-containing semiconductor layer.

12. The method of claim 11, wherein said nanocrystalline silicon-containing semiconductor layer includes nanocrystalline intrinsic silicon.

13. The method of claim 1, wherein said plasma treatment converts a surface portion of said amorphous p-doped silicon-containing semiconductor layer into said nanocrystalline silicon-containing semiconductor layer.

14. The method of claim 11, wherein said nanocrystalline silicon-containing semiconductor layer includes nanocrystalline p-doped silicon.

15. The method of claim 1, further comprising:
forming an amorphous intrinsic silicon-containing semiconductor layer on said nanocrystalline silicon-containing semiconductor layer; and
forming an n-doped semiconductor layer on said amorphous intrinsic silicon-containing semiconductor layer.

16. The method of claim 15, wherein said substrate is optically transparent, and said method further comprises:
forming a transparent conductive material layer on said substrate, wherein said amorphous p-doped silicon-containing semiconductor layer is formed on said transparent conductive material layer; and
forming at least one back reflector layer on said n-doped semiconductor layer.

17. The method of claim 1, wherein said nanocrystalline silicon-containing semiconductor layer has a thickness from 0.5 nm to 5 nm, and said amorphous p-doped silicon-containing semiconductor layer has a thickness from 5 nm to 300 nm.

18. A photovoltaic device comprising:
an amorphous p-doped silicon-containing semiconductor layer located on a substrate; and
a nanocrystalline silicon-containing semiconductor layer contacting a surface of said amorphous p-doped silicon-containing semiconductor layer.

19. The photovoltaic device of claim 18, wherein said nanocrystalline silicon-containing semiconductor layer includes carbon.

20. The photovoltaic device of claim 19, wherein said nanocrystalline silicon-containing semiconductor layer is a nanocrystalline intrinsic carbon-doped silicon layer or a nanocrystalline p-doped carbon-doped silicon layer.

21. The photovoltaic device of claim 20, wherein said amorphous p-doped silicon-containing semiconductor layer is an amorphous p-doped silicon layer, and said photovoltaic device has an open circuit voltage that is equal to or greater than 800 mV.

22. The photovoltaic device of claim 18, wherein said nanocrystalline silicon-containing semiconductor layer includes nanocrystalline intrinsic silicon.

23. The photovoltaic device of claim 18, wherein said nanocrystalline silicon-containing semiconductor layer includes nanocrystalline p-doped silicon.

24. The photovoltaic device of claim 18, further comprising:
an amorphous intrinsic silicon-containing semiconductor layer contacting said nanocrystalline silicon-containing semiconductor layer; and
an n-doped semiconductor layer contacting said amorphous intrinsic silicon-containing semiconductor layer.

25. The photovoltaic device of claim 18, wherein said substrate is optically transparent, and said photovoltaic device further comprises:
a transparent conductive material layer contacting said substrate and said amorphous p-doped silicon-containing semiconductor layer; and
at least one back reflector layer contacting said n-doped semiconductor layer.
